(19) United States
(12) Patent Application Publication
(10) Pub. No.: US 2017/0257077 A1
(43) Pub. Date: Sep. 7, 2017

(54) CRYSTAL RESONATOR

(71) Applicant: NIHON DEMPA KOGYO CO., LTD., Tokyo (JP)

(72) Inventors: Shigeru OBARA, Saitama (JP); Tetsuya SATO, Saitama (JP); Masaaki NAKAHARA, Saitama (JP); Tomonori SHIBAZAKI, Saitama (JP); Yuki OI, Saitama (JP); Yuya NISHIMURA, Saitama (JP)

(73) Assignee: NIHON DEMPA KOGYO CO., LTD., Tokyo (JP)

(21) Appl. No.: 15/447,130

(22) Filed: Mar. 2, 2017

(30) Foreign Application Priority Data
Mar. 4, 2016 (JP) 2016-042267

(51) Int. Cl. H03H 9/19; H03H 9/13

(52) U.S. Cl. CPC H03H 9/19; H03H 9/132

(57) ABSTRACT

A crystal resonator includes a flat plate-shaped crystal element and excitation electrodes. The crystal element has principal surfaces parallel to an X′-axis and a Z′-axis. The X′-axis is an axis of rotating an X-axis as a crystallographic axis of a crystal in a range of 15 degrees to 25 degrees around a Z-axis as a crystallographic axis of the crystal. The Z′-axis is an axis of rotating the Z-axis in a range of 33 degrees to 35 degrees around the X′-axis. The excitation electrodes are formed on the respective principal surfaces of the crystal element. The excitation electrodes are each formed into an elliptical shape. The elliptical shape has a long axis extending in a direction in a range of −5 degrees to +15 degrees with respect to a direction that the X′-axis extends.

### CROSS-REFERENCE TO RELATED APPLICATIONS

This application is based on and claims priority under 35 U.S.C. §119 to Japanese Patent Application No. 2016-042267, filed on Mar. 4, 2016, the entire content of which is incorporated herein by reference.

### TECHNICAL FIELD

This disclosure relates to a crystal resonator where a doubly rotated cut crystal element is used.

### DESCRIPTION OF THE RELATED ART

There has been known a doubly rotated crystal resonator that uses a doubly rotated cut crystal element. The doubly rotated cut crystal element is formed by cutting a crystal parallel to an X′-axis, an axis of rotating an X-axis as a crystallographic axis of the crystal by φ degrees around a Z-axis as a crystallographic axis and a Z′-axis, an axis of rotating the Z-axis around the X′-axis by θ degrees. For example, Japanese Unexamined Patent Application Publication No. 5-243890 describes an SC-cut crystal resonator with, for example, φ of approximately 22 degrees and θ of approximately 34 degrees. Such doubly rotated crystal resonator features good thermal shock property compared with that of an AT-cut crystal resonator and exhibits a zero temperature coefficient at a comparatively high temperature around 80° C. Accordingly, the doubly rotated crystal resonator is housed in an oven heated to a constant temperature at, for example, around 80° C. and is used as a highly-stable crystal controlled oscillator.

However, the doubly rotated crystal resonator as disclosed in JP-A-5-243890 has the following problems. Unwanted responses in a contour mode and a flexure mode combine with the main vibration. This is likely to cause a sudden frequency change and a change in crystal impedance (CI) due to a temperature change. Since the doubly rotated crystal resonator and the AT-cut crystal resonator have modes of vibration different from one another, it is difficult to reduce the unwanted response with the use of the technique of the AT-cut crystal resonator for the doubly rotated crystal resonator as it is.

A need thus exists for a crystal resonator which is not susceptible to the drawback mentioned above.

### SUMMARY

According to an aspect of this disclosure, there is provided a crystal resonator that includes a flat plate-shaped crystal element and excitation electrodes. The crystal element has principal surfaces parallel to an X′-axis and a Z′-axis. The X′-axis is an axis of rotating an X-axis as a crystallographic axis of a crystal in a range of 15 degrees to 25 degrees around a Z-axis as a crystallographic axis of the crystal. The Z′-axis is an axis of rotating the Z-axis in a range of 33 degrees to 35 degrees around the X′-axis. The excitation electrodes are formed on the respective principal surfaces of the crystal element. The excitation electrodes are each formed into an elliptical shape. The elliptical shape has a long axis extending in a direction in a range of −5 degrees to +15 degrees with respect to a direction that the X′-axis extends.

### BRIEF DESCRIPTION OF THE DRAWINGS

The foregoing and additional features and characteristics of this disclosure will become more apparent from the following detailed description considered with reference to the accompanying drawings, wherein:

FIG. 1 is an explanatory drawing of a doubly rotated cut crystal element 110;

FIG. 2A is a plan view of a crystal resonator 100, and FIG. 2B is a cross-sectional view taken along a line IIB-IIB in FIG. 2A;

FIG. 3A is a plan view of a crystal resonator 200a, and FIG. 3B is a plan view of a crystal resonator 200b;

FIG. 4A is a schematic plan view of a crystal resonator 100a, and FIG. 4B is a schematic plan view of a crystal resonator 100b;

FIG. 5A is a plan view of an excitation electrode 320, FIG. 5B is a plan view of a crystal resonator 300a, and FIG. 5C is a plan view of a crystal resonator 300b;

FIG. 6A is a plan view of a crystal resonator 400, FIG. 6B is a cross-sectional view taken along a line VIB-VIB in FIG. 6A, and FIG. 6C is a graph showing a relationship between a wavelength of an unnecessary vibration and a frequency; and

FIG. 7A is a graph showing a change in CI value according to a temperature with an inclination length of 0 μm, FIG. 7B is a graph showing the change in CI value according to the temperature with the inclination length of 50 μm, FIG. 7C is a graph showing the change in CI value according to the temperature with the inclination length of 55 μm, and FIG. 7D is a graph showing the change in CI value according to the temperature with the inclination length of 400 μm.

### DETAILED DESCRIPTION

The embodiments of this disclosure will be described in detail with reference to the drawings. The embodiments in the following description do not limit the scope of the disclosure unless otherwise stated.

### First Embodiment

<Configuration of Crystal Resonator 100 >

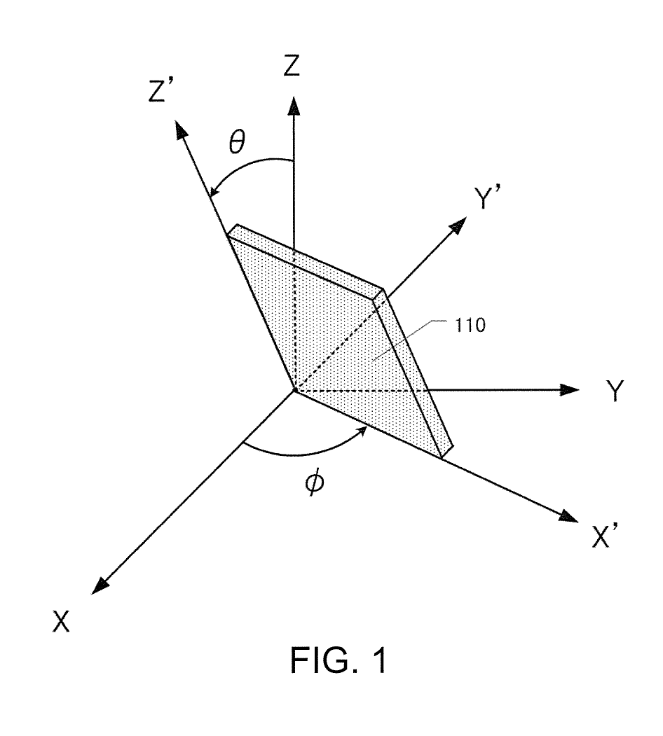

FIG. 1 is an explanatory drawing of a doubly rotated cut crystal element 110. FIG. 1 denotes crystallographic axes for a crystal as an X-axis, a Y-axis, and a Z-axis. The doubly rotated cut crystal element 110 is formed by cutting the crystal parallel to an X′-axis, an axis of rotating the X-axis as the crystallographic axis of the crystal around the Z-axis by φ degrees as the crystallographic axis of the crystal and a Z′-axis, an axis of rotating the Z-axis around the X′-axis by θ degrees. Therefore, the doubly rotated cut crystal element 110 is formed such that the X′-Z′ surface becomes a principal surface. FIG. 1 shows a Y′-axis perpendicular to the X′-axis and the Z′-axis.

As the doubly rotated cut crystal element illustrated in FIG. 1, for example, there has been known an SC-cut crystal element with φ of approximately 22 degrees and θ of approximately 34 degrees, an IT-cut crystal element with φ of approximately 19 degrees and θ of approximately 34 degrees, and an FC-cut crystal element with φ of approximately 15 degrees and θ of 34.33 degrees. These crystal elements have φ between 15 degrees and 25 degrees and θ between 33 degrees and 35 degrees. The following gives the description assuming the use of the doubly rotated cut crystal element with θ between 15 degrees and 25 degrees and θ between 33 degrees and 35 degrees.

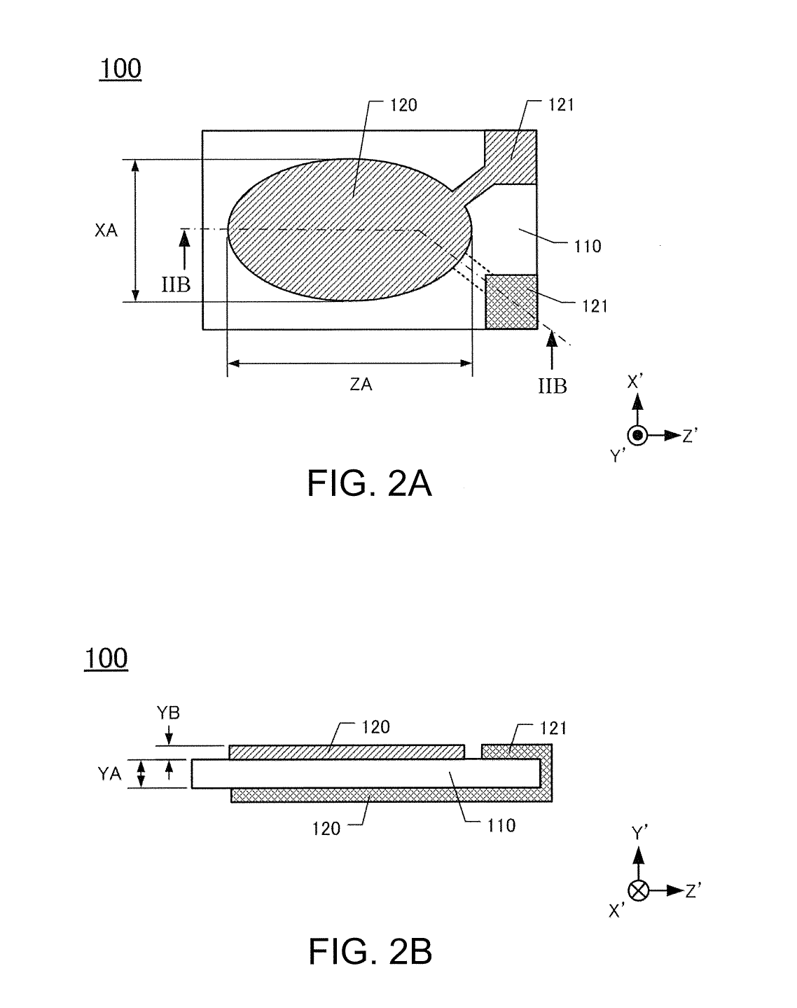

FIG. 2A is a plan view of the crystal resonator 100. The crystal resonator 100 includes a crystal element 110 and excitation electrodes 120. The crystal element 110 is formed into a rectangular flat plate shape whose long sides extend in the Z′-axis direction and short sides extend in the X′-axis direction. Arranging the shape of the square-plate-shaped crystal resonator is easy and the production cost can be reduced low, and thereby the crystal resonator is preferable.

The excitation electrodes 120 are formed on respective front and back principal surfaces (the respective surfaces on the +Y′-axis side and the −Y′-axis side) of the crystal element 110. The respective excitation electrodes 120 have the identical shape and are formed to overlap with one another in the Y′-axis direction. The excitation electrode 120 is formed into the rectangular shape whose long axis extends in the Z′-axis direction and short axis extends in the X′-axis direction. Extraction electrodes 121 are each extracted from the excitation electrodes 120 to both ends of a side on the +Z′-axis side of the crystal element 110.

Conventionally, while the crystal element has been formed into the square plate shape in accordance with downsizing of the crystal resonator, to provide the excitation electrode with a large area in order to achieve a good electric constant, the excitation electrode has been formed into the square shape. However, the square excitation electrode is likely to cause a coupling of an unwanted response in a flexure mode with a reflected wave from an end surface of the crystal element. This has caused a variation of and an increase in CI value. In contrast to this, a circular excitation electrode can reduce the reflected wave from the end surface of the crystal element and can prevent the coupling, thereby ensuring preventing the variation of and the increase in CI value. Furthermore, since an elliptical excitation electrode can widen the area of the excitation electrode to achieve the good electric constant and also can prevent the variation of and the increase in CI value similar to the circular excitation electrode, the elliptical excitation electrode is preferable.

In the case where a length ZA of the long axis is in a range of 1.1 times to 2.0 times of a length XA of the short axis, the variation of and the increase in CI value tend to be reduced and therefore such length is preferable. In the case where the length ZA of the long axis is smaller than 1.1 times of the length XA of the short axis, since the excitation electrode has the shape close to the circular shape, the area of the excitation electrode cannot be widened. In the case where the length ZA of the long axis is larger than 2.0 times of the length XA of the short axis, the effects of ensuring preventing the variation of and the increase in CI value, which are seen in the circular excitation electrode, probably weaken.

FIG. 2B is a cross-sectional view taken along a line IIB-IIB in FIG. 2A. A thickness of the crystal element 110 is denoted as YA and a thickness of each of the excitation electrodes 120 is denoted as YB. Since an oscillation frequency of the crystal resonator is inversely proportional to the thickness of the crystal element, the thickness YA is determined according to the oscillation frequency of the crystal resonator 100. The thickness YB is preferably formed to be the thickness between 700 Å and 2500 Å and is especially preferably formed between 1200 Å and 1600 Å. The extremely thinned excitation electrode fails to function as the electrode and therefore cannot confine a main vibration. The extremely thickened excitation electrode increases a weight of the electrode, resulting in the increase in CI value and the variation of CI value. Accordingly, considering these factors, the thickness is adjusted to be in the optimal range. There is a preferable relationship between the thickness YA and the thickness YB. The thickness YB with the value between 0.03% and 0.18% of the thickness YA generates a small variation of CI value and therefore is preferable.

<Configurations of Crystal Resonator 200a and Crystal Resonator 200b>

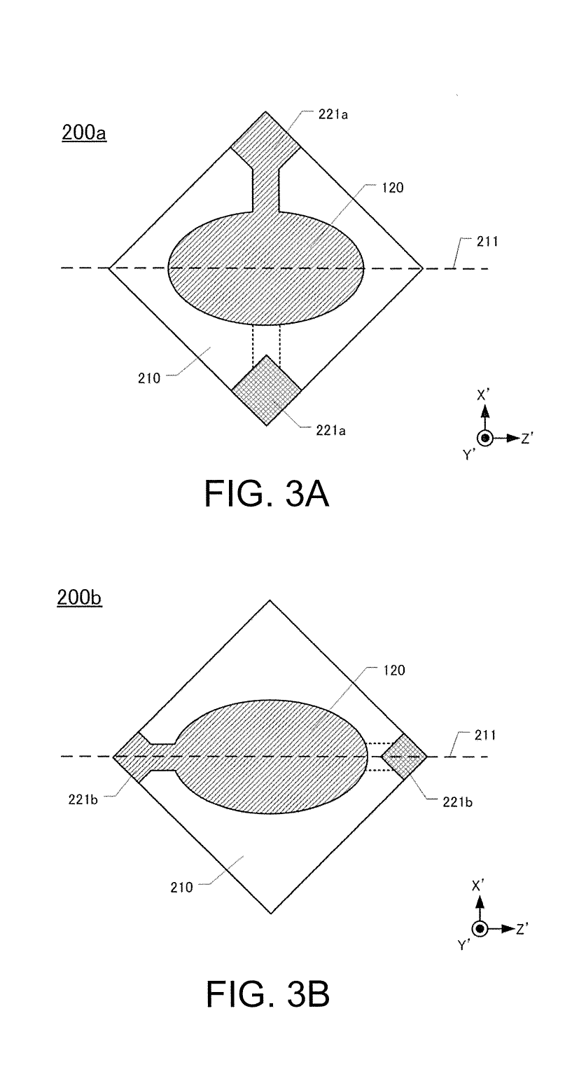

FIG. 3A is a plan view of the crystal resonator 200a. The crystal resonator 200a includes a crystal element 210 with square planar surface, the excitation electrodes 120 formed on both principal surfaces of the crystal element 210, and extraction electrodes 221a extracted from the respective excitation electrodes 120. While the crystal element 110 (see FIG. 2A) is formed into the rectangular shape, arranging the shape of the square crystal element 210, which has the short side length identical to the long side length, is also easy and can reduce the production cost. Therefore, the square crystal element 210 is preferable. The crystal element 210 has one diagonal line 211 parallel to the Z′-axis. The long axis of the excitation electrode 120 is formed to go along the diagonal line 211. The larger area of the excitation electrode makes the electric constant stable and therefore is preferable. Meanwhile, forming the excitation electrode 120 along the diagonal line 211 allows forming the size of the area of the excitation electrode 120 large in the crystal element 210 with predetermined size and therefore is preferable. With the crystal resonator 200a, the extraction electrodes 221a are each extracted to corners on a diagonal line of the crystal element 210 on the +X′-axis side and the −X′-axis side of the crystal element 210.

FIG. 3B is a plan view of the crystal resonator 200b. The crystal resonator 200b includes the crystal element 210 with square planar surface, the excitation electrodes 120 formed on both principal surfaces of the crystal element 210, and extraction electrodes 221b extracted from the respective excitation electrodes 120. The extraction electrodes 221b are extracted to corners of the crystal element 210 on the +Z′-axis side and the −Z′-axis side of the excitation electrodes 120.

In both cases of FIGS. 3A and 3B, the crystal element is held at the corner portions on the diagonal line of the crystal element, ensuring stably holding the crystal element. However, the holding positions are not limited to these. FIGS. 3A and 3B show the examples where the diagonal lines of the crystal elements are parallel to the Z′-axis and therefore the corner portions of the crystal element are positioned on the Z′-axis and the X′-axis. Note that, considering an influence given to the support or a similar influence, the diagonal line of the crystal element meets a preferable positional relationship where the diagonal line is not parallel to the Z′-axis and is positioned in a range of ±10 degrees with respect to the Z′-axis, that is, the corner portions of the crystal element may be positioned on a line displaced from the Z′-axis and the X′-axis by predetermined degrees in some cases.

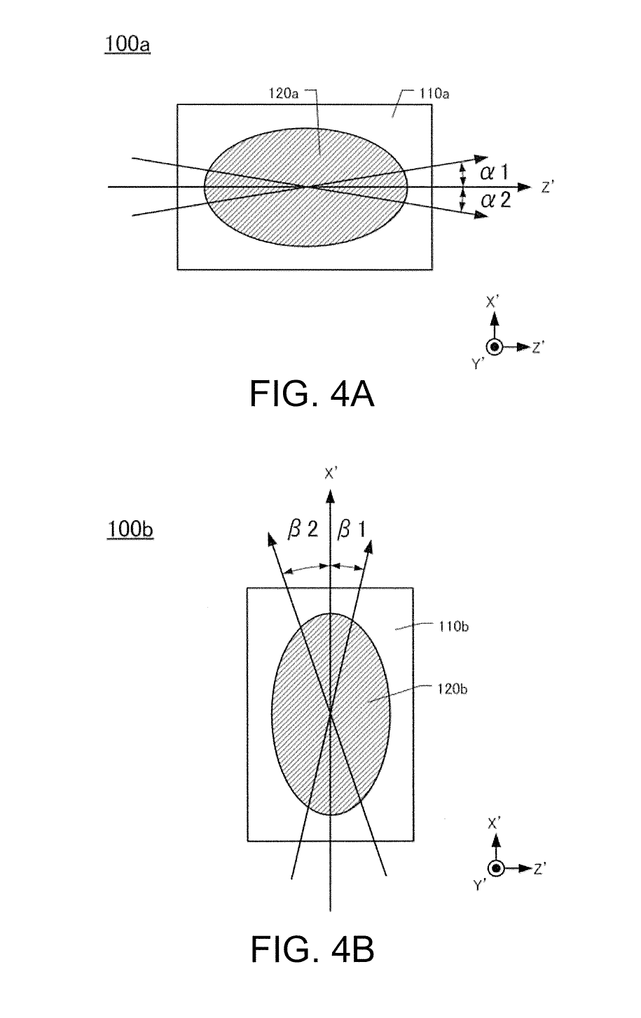

FIG. 4A is a schematic plan view of a crystal resonator 100a. The crystal resonator 100a includes a crystal element 110a and an excitation electrode 120a. Although an extraction electrode and a similar member are also formed on the crystal resonator 100a, FIG. 4A illustrates only the crystal element 110a and the excitation electrode 120a. The excitation electrode 120a is formed into an elliptical shape whose long axis extends in the Z′-axis direction. The crystal element 110a is formed into a rectangular shape whose long sides extend in the Z′-axis direction.

The shape of the excitation electrode is preferably the elliptical shape. However, with the excitation electrode having the long axis extending in the Z′-axis direction, the flexure vibration, which is the unwanted response, transmitted in the Z′-axis direction can be reduced. This can reduce the increase in CI value and therefore is preferable. Assuming that an angle formed by rotating the Z′-axis counterclockwise as α1 and an angle formed by rotating the Z′-axis clockwise as α2, when the direction that the long axis of the excitation electrode 120a extends is a direction withα1 and α2 in a range of 5 degrees, an effect that the flexure vibration can be reduced is likely to obtained. That is, assuming that the counterclockwise direction as a positive direction while the clockwise direction as a negative direction, the case where the long axis of the excitation electrode extends in the direction in the range of ±5 degrees with respect to the direction that the Z′-axis extends is preferable.

FIG. 4B is a schematic plan view of a crystal resonator 100b. The crystal resonator 100b includes a crystal element 110b and an excitation electrode 120b. Although an extraction electrode and a similar member are also formed on the crystal resonator 100b, FIG. 4B illustrates only the crystal element 110b and the excitation electrode 120b. The excitation electrode 120b is formed into the elliptical shape whose long axis extends in the X′-axis direction. The crystal element 110b is formed into the rectangular shape whose long sides extend in the X′-axis direction.

In the case where the long axis of the excitation electrode extends in the X′-axis direction like the excitation electrode 120b, an end surface reflection of the unwanted response on the crystal resonator 100b can be reduced, thereby ensuring reducing the increase in CI value. In the case where the long axis of the excitation electrode extends in a range of −5 degrees to +15 degrees with respect to the X′-axis of the crystal element, that is, in the case of the extension in a range of β1 of −5 degrees and β2 of +15 degrees in FIG. 4B, the increase in CI value can be reduced.

FIGS. 4A and 4B show the examples where the one side of the crystal element is parallel to the Z′-axis or the X′-axis. Specifically, FIG. 4A shows the example where the one long side of the rectangular crystal element is parallel to the Z′-axis, and FIG. 4B shows the example where the one short side of the rectangular crystal element is parallel to the Z′-axis. Note that, considering the influence given to the support or a similar influence, the one side of the crystal element meets a preferable positional relationship where the one side is not parallel to the Z′-axis and is positioned in a range of ±10 degrees with respect to the Z′-axis, that is, the corner portions of the crystal element may be positioned on a line displaced from the Z′-axis and the X′-axis by predetermined degrees in some cases.

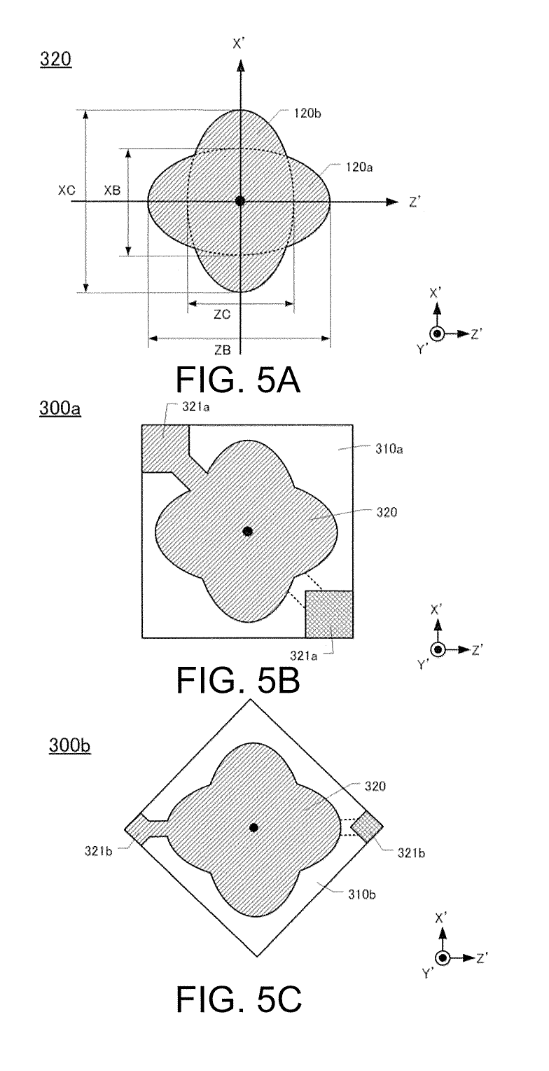

FIG. 5A is a plan view of an excitation electrode 320. The excitation electrode 320 is formed into a shape of overlapping the excitation electrode 120a illustrated in FIG. 4A with the excitation electrode 120b illustrated in FIG. 4B with the centers of the excitation electrode 120a and the excitation electrode 120b matched with one another. Assume that a length of the long axis of the excitation electrode 120a as ZB and a length of the short axis as XB, and a length of the long axis of the excitation electrode 120b as XC and a length of the short axis as ZC. Then, similar to the excitation electrode 120 illustrated in FIG. 2A, the excitation electrode 320 is formed such that the length Z13 of the long axis of the excitation electrode 120a becomes in a range of 1.1 times to 2.0 times of the length XB of the short axis while the length XC of the long axis of the excitation electrode 120b becomes in a range of 1.1 times to 2.0 times of the length ZC of the short axis. The lengths of the short axes and the long axes of the excitation electrode 120a and the excitation electrode 120b may be identical to or different from one another.

With the excitation electrode having the long axis parallel to the Z′-axis like the excitation electrode 120a, the flexure vibration, which is the unwanted response, transmitted in the Z′-axis direction can be reduced. With the excitation electrode having the long axis parallel to the X′-axis like the excitation electrode 120b, the end surface reflection of the unwanted response can be reduced. Since the excitation electrode 320 is formed into the shape of combining the elliptical shape whose long axis extends in the Z′-axis direction and the elliptical shape whose long axis extends in the X′-axis direction, the excitation electrode 320 has the features of both of the excitation electrode 120a and the excitation electrode 120b.

FIG. 5B is a plan view of a crystal resonator 300a. The crystal resonator 300a includes a crystal element 310a, the excitation electrodes 320, and extraction electrodes 321a. The excitation electrodes 320 are formed on both principal surfaces of the crystal element 310a. The extraction electrodes 321a are each extracted from the excitation electrodes 320. FIG. 5B shows an example where the length ZB and the length XC have the identical length, the crystal element 310a has a square planar surface, and sides of the crystal element 310a are each formed to be parallel to the Z′-axis or the X′-axis. The extraction electrodes 321a are each extracted from the excitation electrodes 320 to a corner on the +X′-axis side and the −Z′-axis side of the crystal element 310a and a corner on the −X′-axis side and the +Z′-axis side on the diagonal line of the crystal element 310a.

The crystal resonator 300a has the respective sides of the crystal element 310a formed extending in the X′-axis and the Z′-axis along the long axes of the excitation electrode 120a and the excitation electrode 120b. This allows forming the wide area of the excitation electrode 320 and therefore is preferable.

FIG. 5C is a plan view of a crystal resonator 300b. The crystal resonator 300b includes a crystal element 310b, the excitation electrodes 320, and extraction electrodes 321b. The excitation electrodes 320 are formed on both principal surfaces of the crystal element 310b. The extraction electrodes 321b are each extracted from the excitation electrodes 320. In FIG. 5C, the length ZB and the length XC have the identical length, the crystal element 310b has the square planar surface, and diagonal lines of the crystal element 310b are formed to be parallel to the Z′-axis and the X′-axis. The extraction electrodes 321b are each extracted from the excitation electrodes 320 to a corner on the +Z′-axis side and a corner on the −Z′-axis side of the crystal element 310b.

FIG. 5B shows the example where the one side of the crystal element is parallel to the Z′-axis. FIG. 5C shows the example where the diagonal line of the crystal element is parallel to the Z′-axis. Note that, considering the influence given to the support or a similar influence, the one side and the diagonal line of the crystal element may be disposed at preferable positions where the one side and the diagonal line are not parallel to the Z′-axis and are positioned in a range of ±10 degrees with respect to the Z′-axis.

The crystal resonator 300b has the diagonal line of the crystal element 310b formed parallel to the Z′-axis or the X′-axis. This allows forming the wide area of the excitation electrode and therefore is preferable.

### Second Embodiment

The formation of an inclined portion whose surface is inclined at a peripheral area of an excitation electrode can also reduce the flexure vibration and the reflected wave. The following describes a crystal resonator with the inclined portion.

<Configuration of Crystal Resonator 400>

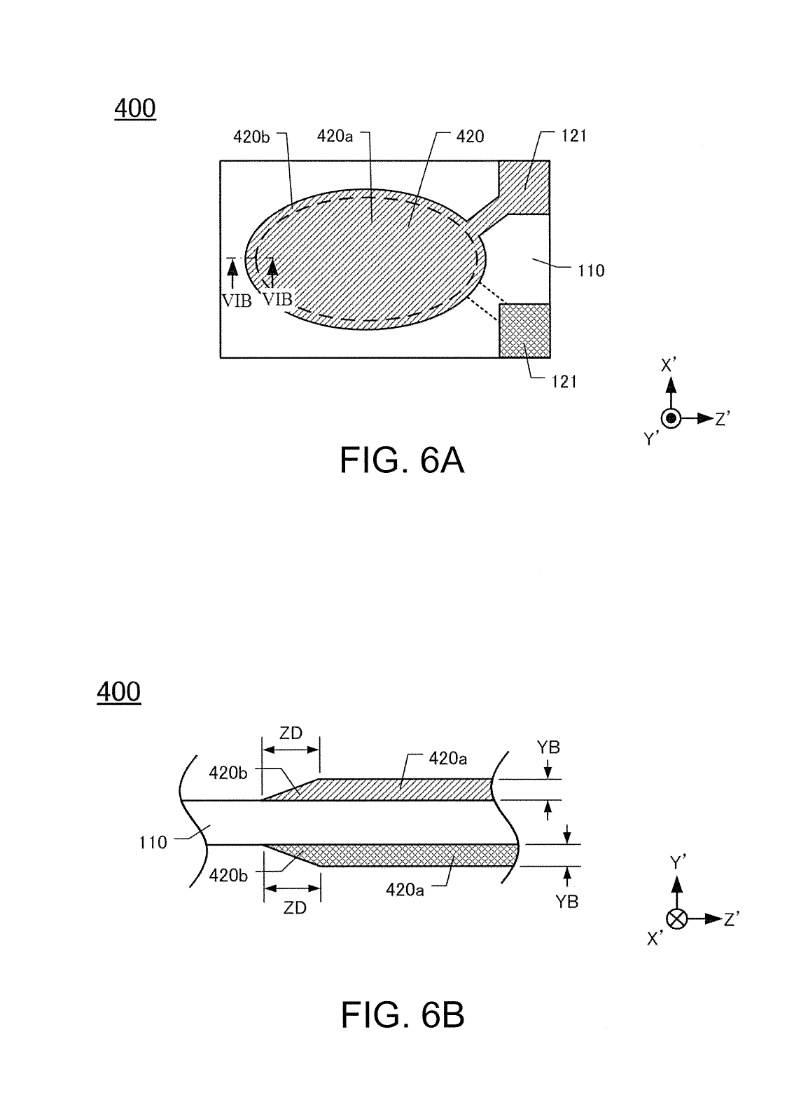

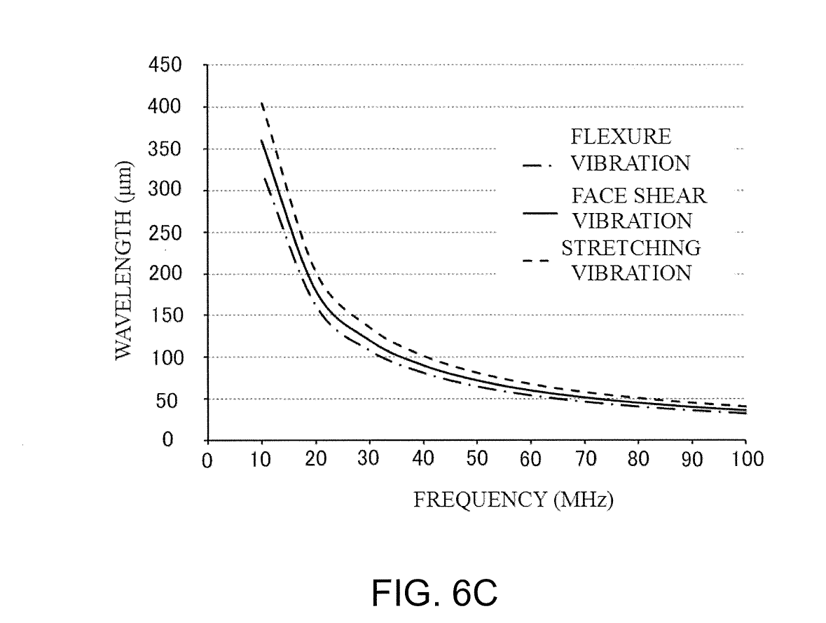

FIG. 6A is a plan view of the crystal resonator 400. The crystal resonator 400 includes the crystal element 110, excitation electrodes 420, and the extraction electrode 121. The excitation electrode 420 is formed into the elliptical shape identical to the excitation electrode 120 illustrated in FIG. 2A. The excitation electrode 420 includes a center portion 420a with constant thickness and an inclined portion 420b. The inclined portion 420b is formed at the peripheral area of the center portion 420a and has a thickness decreasing from the inner peripheral side to the outer peripheral side. FIG. 6A indicates the inside of the dotted line on the excitation electrode 420 as the center portion 420a and the outside of the dotted line as the inclined portion 420b.

FIG. 6B is a cross-sectional view taken along a line VIB-VIB in FIG. 6A. The excitation electrode 420 is formed such that a thickness of the center portion 420a is YB and the thickness of the inclined portion 420b is thinned with a length from the inner peripheral side to the outer peripheral side (inclination length) in a range of a length ZD. With the length ZD of the inclined portion 420b larger than ½ of the wavelength of unnecessary vibrations, the unnecessary vibrations can be reduced in the excitation electrode 420 and thereby the CI value can reduced. The reason for this is considered that the unnecessary vibrations due to the reflected wave from the end surface of the crystal element or a similar factor are attenuated at the inclined portion.

FIG. 6C is a graph showing the relationship between the wavelength of the unnecessary vibration and the frequency. FIG. 6C shows the frequency (MHz) of the crystal resonator on the horizontal axis and shows the wavelength (μm) of the unnecessary vibration on the vertical axis. A scale of the vertical axis is given in units of 50 μm. The unnecessary vibration occurred in association with the main vibration includes various vibrations such as the flexure vibration, a face shear vibration, and a stretching vibration. FIG. 6C shows the flexure vibration by dashed-dotted line, shows the face shear vibration by the solid line, and shows the stretching vibration by the dotted line.

Since the flexure vibration affects the CI value of the doubly rotated crystal resonator most among the unnecessary vibrations, reducing the flexure vibration becomes important to reduce the CI value. For example, in the case where the flexure vibration has the wavelength at 162.0 μm with the oscillation frequency of the crystal resonator of 20 MHz, configuring the length ZD to 81.0 μm or more, which is the half of the wavelength of the flexure vibration, can substantially reduce the flexure vibrations. Since the wavelengths of the other unnecessary vibrations such as the face shear vibration and the stretching vibration close to the wavelength of the flexure vibration, the inclined portion for the flexure vibration can also reduce the other unnecessary vibrations.

<Inclination Length>

The following describes results of measuring and obtaining the relationship between the CI value and the temperature with the inclination length changed in the case where the excitation electrode with a thickness of 1400 Å and a diameter of 0.6 A mm was formed on a crystal element with an A-mm square and was oscillated at 20 MHz.

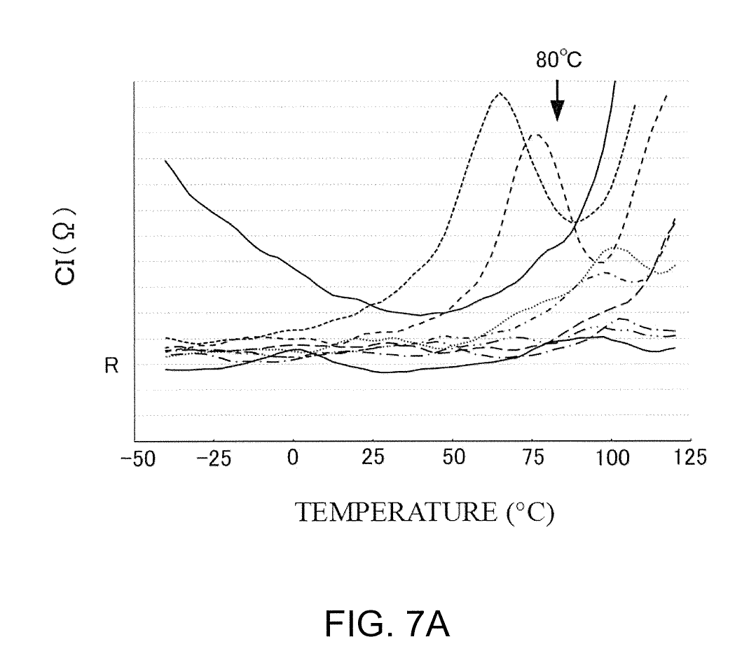

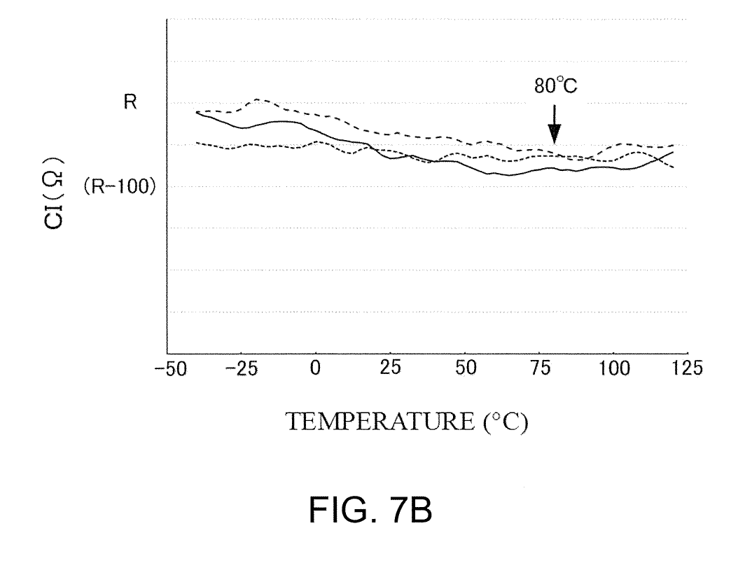

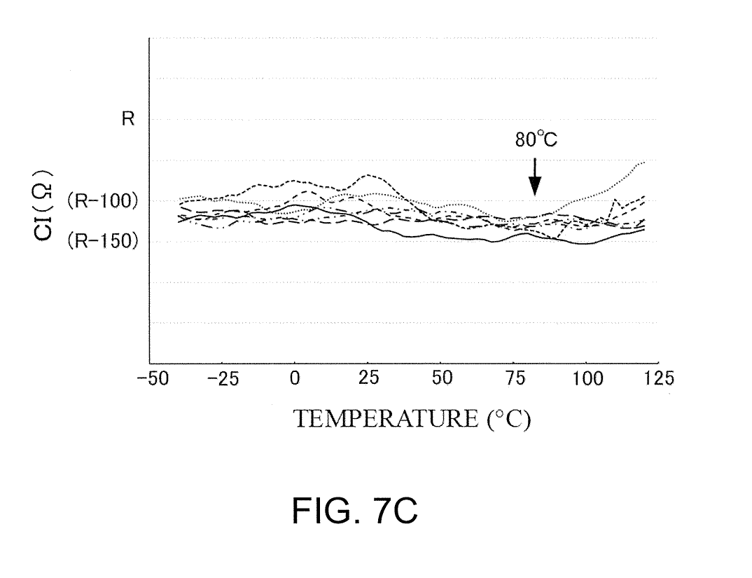

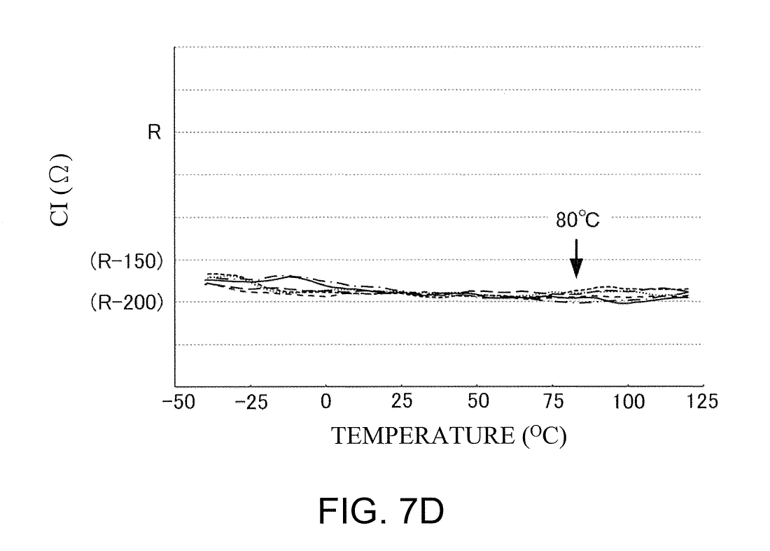

FIG. 7A is a graph showing the change in CI value according to the temperature with the inclination length of 0 μm. The horizontal axis indicates the temperature of the crystal resonator, and the vertical axis indicates the CI value. Note that, the drawings in FIGS. 7A to 7D each denote a common reference CI value as a guideline in each experiment as R. FIG. 7A describes the CI with a scale in units of 100 Ω with respect to R. FIG. 7A shows the change in CI value of the nine crystal resonators according to the temperature. The crystal resonators in FIG. 7A each include the excitation electrodes with the inclination length of 0 μm. That is, FIG. 7A shows the state where the inclined portion is not formed.

It is found from FIG. 7A that a tendency of the change in CI value according to the temperature substantially differs depending on the quartz crystal resonators; therefore, the CI value is unstable. For example, at 80° C., the temperature at which a doubly rotated crystal resonator is possibly used, the lowest CI value is approximately (R+50) and the highest CI value is approximately (R+850) Ω. That is, the crystal resonators in FIG. 7A cause the variation of approximately 800 Ω at 80° C.

FIG. 7B is a graph showing the change in CI value according to the temperature with the inclination length of 50 μm. FIG. 7B shows the change in CI value of the three crystal resonators according to the temperature and provides a scale at intervals of 50 Ω on the vertical axis. The inclination length of the excitation electrodes of the respective crystal resonators is 50 μm. The CI values in FIG. 7B fall within a range of approximately from (R−100) Ω to R Ω. Especially, at 80° C., the temperature at which the doubly rotated crystal resonator is possibly used, the lowest CI value is (R−77.94) and the highest CI value is (R−58.89) Ω. That is, the crystal resonators in FIG. 7B cause the variation of 18.05 Ω at 80° C. These results show that, compared with the crystal resonators shown in FIG. 7A, the formation of the inclined portion substantially reduces and stabilizes the CI value.

FIG. 7C is a graph showing the change in CI value according to the temperature with the inclination length of 55 μm. FIG. 7C shows the change in CI value of the seven crystal resonators according to the temperature and provides a scale at intervals of 50 Ω on the vertical axis. The inclination length of the excitation electrodes of the respective crystal resonators shown in FIG. 7C is 55 μm. That is, the inclination length differs from the inclination length in the crystal resonators in FIG. 7B. The CI values in FIG. 7C fall within a range of approximately from (R−150) Ω to (R−100) Ω. Especially, at 80° C., the temperature at which the doubly rotated crystal resonator is possibly used, the lowest CI value is (R−140.11) Ω and the highest CI value is (R−120.23) Ω. That is, the crystal resonators in FIG. 7C cause the variation of 19.88 Ω at 80° C.

The crystal resonators in FIG. 7C show that the formation of the inclined portion substantially reduces and stabilizes the CI value compared with the crystal resonators in FIG. 7A, similar to the crystal resonators in FIG. 7B. It is seen that the crystal resonators in FIG. 7C entirely reduce the CI value by around 50 Ω compared with the crystal resonators in FIG. 7B. It is thought that this result is caused by the inclination length of the crystal resonators in FIG. 7C longer than that of the crystal resonators in FIG. 7B. Furthermore, the reason that only the 5-μm difference of the inclination length reduces the CI value to almost 50 Ω is considered as follows. Since the inclination lengths in FIG. 7B and FIG. 7C are shorter than 81.0 μm, which is ½ of the wavelength of the flexure vibration, at 20 MHz, the flexure vibration is not sufficiently reduced. Accordingly, the flexure vibration to be reduced substantially differs depending on the slight difference of the inclination length.

FIG. 7D is a graph showing the change in CI value according to the temperature with the inclination length of 400 μm. FIG. 7D shows the change in CI value of the six crystal resonators according to the temperature and provides a scale at intervals of 50 Ω on the vertical axis. In the respective crystal resonators shown in FIG. 7D, the inclination length is 400 μm. The CI values in FIG. 7D fall within a range of approximately from (R−200)Ω to (R−150) Ω. Especially, at 80° C., the temperature at which the doubly rotated crystal resonator is possibly used, the lowest CI value is (R−201.3)Ω and the highest CI value is (R−189.4) Ω. That is, the crystal resonators in FIG. 7D cause the variation of 11.9 Ω at 80° C.

Compared with the crystal resonators in FIG. 7A to FIG. 7C, the crystal resonators in FIG. 7D have the low CI values and the small variations of CI value. It is thought that these results are caused by the formation of the long inclination length. It is thought that, since the crystal resonators in FIG. 7D have the inclination length longer than 81.0 μm, which is ½ of the wavelength of the flexure vibration, at 20 MHz, the flexure vibration is sufficiently reduced.

The crystal resonators as shown in FIG. 7D can be formed by, for example, a method of using a metallic mask formed from a metal plate by a photolithography technology and a wet etching technique. Specifically, the mask is an overhang-shaped mask obtained using a property of promoting side etching together with etching in a thickness direction of the metal plate. Alternatively, a large number of thin masks whose opening dimensions become smaller little by little are laminated, and a spot welding is performed on these masks, thus forming one mask. The use of these overhang-shaped mask or large number of laminated thin masks allows forming the crystal resonators in FIG. 7D.

A crystal resonator of a second aspect includes a flat plate-shaped crystal element and excitation electrodes. The crystal element has principal surfaces parallel to an X′-axis and a Z′-axis. The X′-axis is an axis of rotating an X-axis as a crystallographic axis of a crystal in a range of 15 degrees to 25 degrees around a Z-axis as a crystallographic axis of the crystal. The Z′-axis is an axis of rotating the Z-axis in a range of 33 degrees to 35 degrees around the X′-axis. The excitation electrodes are formed on the principal surfaces of the crystal element. The excitation electrodes are each formed into an elliptical shape. The elliptical shape has a long axis extending in a direction in a range of ±5 degrees with respect to a direction that the Z′-axis extends.

The crystal resonators of third aspects according to the first aspect and the second aspect is configured as follows. The crystal element is formed into a square or a rectangle where one diagonal line is in a range of ±10° with respect to a Z′-axis. Alternatively, the crystal element is formed into a square or a rectangle where one side is in a range of ±10° with respect to the Z′-axis (Note that the square and the rectangle include an approximately square and an approximately rectangle where a corner portion of the crystal element has a rounded shape or a similar shape). The reason of describing the range as ±10° here is that the excitation electrodes according to this disclosure are disposed at the specific positions within this range and further an influence given to the support of the crystal element can be reduced and the crystal element easy to be processed is selectable.

The crystal resonator of a fourth aspect according to any of the first aspect to the third aspect is configured as follows. A ratio of the long axis to a short axis of the elliptical shape is in a range of 1.1:1 to 2.0:1.

A crystal resonator of a fifth aspect includes a flat plate-shaped crystal element and excitation electrodes. The crystal element has principal surfaces parallel to an X′-axis and a Z′-axis. The X′-axis is an axis of rotating an X-axis as a crystallographic axis of a crystal in a range of 15 degrees to 25 degrees around a Z-axis as a crystallographic axis of the crystal. The Z′-axis is an axis of rotating the Z-axis in a range of 33 degrees to 35 degrees around the X′-axis. The excitation electrodes are formed on the principal surfaces of the crystal element. The excitation electrodes are each formed into a shape of combining a first elliptical shape and a second elliptical shape. The first elliptical shape has a long axis extending in a direction in a range of −5 degrees to +15 degrees with respect to a direction that the X′-axis extends. The second elliptical shape has a long axis extending in a direction in a range of ±5 degrees with respect to a direction that the Z′-axis extends.

The crystal resonator of a sixth aspect according to the fifth aspect is configured as follows. The first elliptical shape has a ratio of the long axis to a short axis in range of 1.1:1 to 2.0:1. The second elliptical shape has a ratio of the long axis to a short axis in a range of 1.1:1 to 2.0:1.

The crystal resonator of a seventh aspect according to any of the first aspect to the sixth aspect is configured as follows. The crystal element vibrates at a predetermined frequency. The excitation electrodes include a center portion and an inclined portion. The center portion has a constant thickness. The inclined portion is formed at a peripheral area of the center portion. The inclined portion has a thickness decreasing from an inner peripheral side to an outer peripheral side. A width between the inner peripheral side and the outer peripheral side of the inclined portion is longer than ½ wavelength of an unnecessary vibration in the crystal element.

The crystal resonator of an eighth aspect according to any of the first aspect to the seventh aspect is configured as follows. The excitation electrode has a thickness 0.03% to 0.18% of a thickness of the crystal element.

With the crystal resonator according to the embodiments, a coupling of an unwanted response to a main vibration is reduced, thereby ensuring reducing a CI value low.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A crystal resonator, comprising:
a crystal element with a flat plate shape that has principal surfaces parallel to an X′-axis and a Z′-axis, the X′-axis being an axis of rotating an X-axis as a crystallographic axis of a crystal in a range of 15 degrees to 25 degrees around a Z-axis as a crystallographic axis of the crystal, the Z′-axis being an axis of rotating the Z-axis in a range of 33 degrees to 35 degrees around the X′-axis; and
excitation electrodes, formed on the respective principal surfaces of the crystal element, wherein
the excitation electrodes are each formed into an elliptical shape, the elliptical shape having a long axis extending in a direction in a range of −5 degrees to +15 degrees with respect to a direction that the X′-axis extends.

2. The crystal resonator according to claim 1, wherein
the crystal element is formed into a square or a rectangle where one diagonal line is in a range of ±10° with respect to the Z′-axis, alternatively,
the crystal element being formed into a square or a rectangle where one side is in a range of ±10° with respect to the Z′-axis.

3. The crystal resonator according to claim 1, wherein
a ratio of the long axis to a short axis of the elliptical shape is in a range of 1.1:1 to 2.0:1.

4. The crystal resonator according to claim 1, wherein:
the crystal element vibrates at a predetermined frequency,
the excitation electrodes include a center portion and an inclined portion, the center portion having a constant thickness, the inclined portion being formed at a peripheral area of the center portion, the inclined portion having a thickness decreasing from an inner peripheral side to an outer peripheral side, and
a width between the inner peripheral side and the outer peripheral side of the inclined portion is longer than ½ wavelength of an unnecessary vibration in the crystal element.

5. The crystal resonator according to claim 1, wherein
the excitation electrode has a thickness 0.03% to 0.18% of a thickness of the crystal element.

6. A crystal resonator, comprising:
a crystal element with a flat plate shape that has principal surfaces parallel to an X′-axis and a Z′-axis, the X′-axis being an axis of rotating an X-axis as a crystallographic axis of a crystal in a range of 15 degrees to 25 degrees around a Z-axis as a crystallographic axis of the crystal, the Z′-axis being an axis of rotating the Z-axis in a range of 33 degrees to 35 degrees around the X′-axis; and
excitation electrodes, formed on the respective principal surfaces of the crystal element, wherein
the excitation electrodes are each formed into an elliptical shape, the elliptical shape having a long axis extending in a direction in a range of ±5 degrees with respect to a direction that the Z′-axis extends.

7. The crystal resonator according to claim 6, wherein
the crystal element is formed into a square or a rectangle where one diagonal line is in a range of ±10° with respect to the Z′-axis, alternatively,
the crystal element being formed into a square or a rectangle where one side is in a range of +10° with respect to the Z′-axis.

8. The crystal resonator according to claim 6, wherein
a ratio of the long axis to a short axis of the elliptical shape is in a range of 1.1:1 to 2.0:1.

9. The crystal resonator according to claim 6, wherein:
the crystal element vibrates at a predetermined frequency,
the excitation electrodes include a center portion and an inclined portion, the center portion having a constant thickness, the inclined portion being formed at a peripheral area of the center portion, the inclined portion having a thickness decreasing from an inner peripheral side to an outer peripheral side, and
a width between the inner peripheral side and the outer peripheral side of the inclined portion is longer than ½ wavelength of an unnecessary vibration in the crystal element.

10. The crystal resonator according to claim 6, wherein
the excitation electrode has a thickness 0.03% to 0.18% of a thickness of the crystal element.

11. A crystal resonator, comprising:
a crystal element with a flat plate shape that has principal surfaces parallel to an X′-axis and a Z′-axis, the X′-axis being an axis of rotating an X-axis as a crystallographic axis of a crystal in a range of 15 degrees to 25 degrees around a Z-axis as a crystallographic axis of the crystal, the Z′-axis being an axis of rotating the Z-axis in a range of 33 degrees to 35 degrees around the X′-axis; and
excitation electrodes, formed on the respective principal surfaces of the crystal element, wherein
the excitation electrodes are each formed into a shape of combining a first elliptical shape and a second elliptical shape, the first elliptical shape having a long axis extending in a direction in a range of −5 degrees to +15 degrees with respect to a direction that the X′-axis extends, the second elliptical shape having a long axis extending in a direction in a range of ±5 degrees with respect to a direction that the Z′-axis extends.

12. The crystal resonator according to claim 11, wherein
the first elliptical shape has a ratio of the long axis to a short axis in range of 1.1:1 to 2.0:1,
the second elliptical shape having a ratio of the long axis to a short axis in a range of 1.1:1 to 2.0:1.

13. The crystal resonator according to claim 11, wherein:
the crystal element vibrates at a predetermined frequency,
the excitation electrodes include a center portion and an inclined portion, the center portion having a constant thickness, the inclined portion being formed at a peripheral area of the center portion, the inclined portion having a thickness decreasing from an inner peripheral side to an outer peripheral side, and
a width between the inner peripheral side and the outer peripheral side of the inclined portion is longer than ½ wavelength of an unnecessary vibration in the crystal element.

14. The crystal resonator according to claim 11, wherein
the excitation electrode has a thickness 0.03% to 0.18% of a thickness of the crystal element.
